(19) United States
(12) Patent Application Publication
(10) Pub. No.: US 2007/0224101 A1
(43) Pub. Date: Sep. 27, 2007

(54) Semiconductor Polishing Composition

(76) Inventors: Yoshiharu Ohta, Nara (JP); Yasuyuki Itai, Nara (JP)

Correspondence Address: HARNESS, DICKEY & PIERCE, P.L.C., P.O. BOX 8910, RESTON, VA, 20195, US

(21) Appl. No.: 10/594,475

(22) PCT Filed: Mar. 28, 2005
(86) PCT No.: PCT/JP05/05769

§ 371 Date: Sep. 28, 2006

(30) Foreign Application Priority Data
Mar. 29, 2004 (JP) P2004-096850

(51) Int. Cl. H01L 21/304; C01B 33/12

(52) U.S. Cl. 423/335

(57) ABSTRACT

A semiconductor polishing composition is provided that can, in at least one embodiment, efficiently polish a semiconductor device with high accuracy while preventing fumed silica from being agglomerated and without causing a polishing flaw in the semiconductor device. Fumed silica, of which a bulk density of powder before dispersed is 50 g/L or more and less than 100 g/L, is used as abrasive grains. This makes it possible to enhance a dispersion state of the fumed silica, and to realize reduction in transportation cost.

### PRIORITY STATEMENT

This application is the national phase under 35 U.S.C. § 371 of PCT International Application No. PCT/JP2005/005769 which has an International filing date of Mar. 28, 2005, which designated the United States of America and which claims priority on Japanese Patent Application number P2004-096850 filed Mar. 29, 2004, the entire contents of which are hereby incorporated herein by reference.

### TECHNICAL FIELD

The present invention generally relates to a semiconductor polishing composition used at a polishing step in a semiconductor manufacturing process.

### BACKGROUND ART

In a field of manufacturing a semiconductor, a technique for flattening a semiconductor layer and a metal layer has become an important elemental technology along with higher integration of a semiconductor device which is made smaller and more multilayered. When an integrated circuit is formed on a wafer, layer deposition on a non-flattened surface having irregularities of electrode wirings etc. will increase a difference in level and extremely deteriorate flatness. Further, in a case of having a large difference in level, it is difficult to focus on both of a concave portion and a convex portion in a photolithography process, thus failing to realize miniaturization of the semiconductor device.

Accordingly, at an appropriate stage of layer deposition, it is necessary to conduct a flattening process on a surface of wafer so as to remove irregularities thereof. The flattening process includes an etch-back process that etching is performed to remove the irregularities, a film forming method that plasma CVD (Chemical Vapor Deposition) or another device/method is used to form a flat film, a fluidizing method that heat treatment is performed to obtain a flat surface, and a selective growth method that a selective CVD or the like is used to fill the concave portion.

The above methods have problems such that applicability thereof depends on a kind of film including an insulting film, a metal film, or other kinds of film, and such that a region which can be flattened is very small. As a flattening process technique that overcomes such problems, CMP (Chemical Mechanical Polishing) is used for flattening.

In the flattening process through the CMP, while a polishing composition suspending fine particles (abrasive grains) therein is being supplied to a pad surface, the pressed polishing pad and the silicon wafer are made to move relatively to each other to thereby polish the surface so that a large area of the wafer surface can be flattened with high accuracy.

A CMP apparatus for conducting the flattening through CMP is composed mainly of a rotating bed portion, a carrier portion, a polishing composition supply portion, and a dressing portion. The rotating bed portion has a polishing pad stuck to an upper surface thereof by use of an adhesive tape or the like. A lower surface of the rotating bed portion is connected to a rotary drive mechanism via a rotary shaft. The carrier portion holds on a lower surface thereof a silicon wafer which is to be polished, by way of a backing member and a retainer ring so that a to-be-processed surface of the silicon wafer is made to abut on the polishing pad. An upper surface of the carrier portion is connected to the rotary drive mechanism via the rotary shaft.

The polishing composition supply portion supplies to a surface of the polishing pad the polishing composition which suspends particles of silica, ceria, alumina, and the like in a medium. The dressing portion has a plate on which industrial diamond particles are electrodeposited and by which a polishing waste-attached portion is scraped off so that the surface of polishing pad having decreased polishing property is recovered.

In the CMP apparatus, the rotating bed portion and the carrier portion are made to rotate by the rotary drive mechanism and at the same time, slurry is supplied to a substantially center portion of the polishing pad while the silicon wafer and the polishing pad are made to move relatively to each other, to thereby polish the to-be processed surface of silicone wafer.

In recent years, as a size set in the design rule of IC (Integrated Circuit) is smaller and smaller, there arises a problem of micro scratches which are generated on the to-be-polished surface of the silicon wafer due to the slurry. A factor for the micro scratches is conceivably an agglomerate of abrasive grains suspended in a medium or coarse particles existing as dispersion defectives.

As a raw material of the polishing composition, fumed silica or colloidal silica is used. Since a purity of the fumed silica is higher than that of the colloidal silica, silica slurry having less impurities can be produced from the fumed silica. However, the silica slurry produced from the fumed silica has a high agglomerating property, with the result that it is difficult to attain a high dispersibility into a medium.

There has been proposed a technique of which purpose is to enhance the dispersibility of the fumed silica. For instance, there is a method where water and fumed silica are mixed under application of a high shearing force to obtain an aqueous dispersion solution containing the fumed silica at a high concentration, water is added to the aqueous dispersion solution to dilute, and thereby a polishing composition containing a desired concentration of fumed silica is obtained (refer to, for instance, Japanese Examined Patent Publication JP-B2 2935125).

Furthermore, there is a method where, under application of a high shearing force, acid and fumed silica are sequentially added to water and mixed, water is further added thereto, and an alkali aqueous solution is added thereto to obtain an aqueous dispersion solution containing fumed silica (refer to, for instance, Japanese Examined Patent Publication JP-B2 2949633).

Still furthermore, there is a method where fumed silica is added, followed by mixing, to water previously adjusted to be of pH 2 to 4, under application of a high shearing force so that a concentration may be 40 to 60% by weight, water is further added to adjust the viscosity of the mixture to 2 to 10000 cps, followed by stirring for 5 min or more under application of a low shearing force, further followed by adding water to adjust a concentration of fumed silica to 10 to 38% by weight, still further followed by adding alkali under strong stirring to adjust the pH to 9 to 12, and thereby an aqueous dispersion solution containing fumed silica is obtained (refer to, for instance, Japanese Unexamined Patent Publication JP-A 2001-26771).

Polishing compounds were actually prepared from fumed silica as a raw material in processes of manufacture described in the above patent publications. In all processes, the dispersibility was enhanced by setting a shearing condition and a concentration of silica. However, the obtained dispersibility was insufficient, and a large number of agglomerates were present in slurry.

### SUMMARY

Fumed silica used as a raw material is preferably transported in a state where a bulk density thereof is made large, from aspects of easiness in handleability and a transportation cost of the raw material. In order to increase the bulk density, the fumed silica needs to be filled in a container for transportation. When being filled in the container, the fumed silica is packed by pressure or the like means. A surface condition etc. of silica particles thus changes depending on the pressure applied thereon. Accordingly, different conditions on transportation make the polishing composition be in different dispersion states even when manufacturing conditions including a shearing force and a mixing time are the same.

An object of an embodiment of the invention is to provide a semiconductor polishing composition that can efficiently polish a semiconductor device with high accuracy while preventing fumed silica from being agglomerated and without causing a polishing flaw in the semiconductor device.

An embodiment of the invention provides a semiconductor polishing composition comprising:

fumed silica as abrasive grains,

the semiconductor polishing composition being obtained by preparing a mixture of an acidic aqueous solution and fumed silica having a bulk density of 50 g/L or more and less than 100 g/L, and an alkali aqueous solution so that pH of the mixture is in a range of 1 to 3 and pH of the alkali aqueous solution is in a range of 12 to 14, and adding the mixture to the alkali aqueous solution continuously or intermittently.

Furthermore, in an embodiment of the invention, it is preferable that a content of the fumed silica is in a range of 10% by weight to 30% by weight based on a total amount of the composition.

Furthermore, in an embodiment of the invention, it is preferable that the alkali aqueous solution contains one or two or more additives selected from a polishing accelerator, an oxidant, an organic acid, a complexing agent, a corrosion inhibitor and a surfactant.

Furthermore, in an embodiment of the invention, it is preferable that alkali contained in the alkali aqueous solution is one or two or more hydroxides selected from ammonium hydroxide, alkali metal hydroxide, and alkaline earth metal hydroxide.

### DETAILED DESCRIPTION OF THE EXAMPLE EMBODIMENTS

Now example embodiments of the invention are described below.

The semiconductor polishing composition according to an embodiment of the invention contains fumed silica as abrasive grains, and a bulk density of powder of the fumed silica before dispersed is preferably 50 g/L or more and less than 100 g/L and more preferably 75 g/L or more and 85 g/L or less.

When a bulk density of the fumed silica is less than 50 g/L, a ratio of air in a container for transportation is high, resulting in difficulty in handling the powder and a very high transportation cost. Further, in a case where the bulk density is 100 g/L or more, a pressure applied at the time of filling the container for transportation is too high, resulting in difficulty of dispersion at the time of manufacturing the composition and furthermore, agglomeration easily caused on transportation or the like occasion after the manufacture.

By setting the bulk density of the fumed silica so as to fall in a preferable range, it is possible to realize a semiconductor polishing composition that can efficiently polish a semiconductor device with high accuracy at a high polishing speed while preventing fumed silica from being agglomerated and without causing a polishing flaw in the semiconductor device. Furthermore, by setting the bulk density so as to be higher than a conventional level, i.e., 50 g/L, it is made easier to handle the powder, and the transportation cost can also be reduced.

Furthermore, by setting the bulk density of the fumed silica so as to be 75 g/L or more and 85 g/L or less, the fumed silica is easily dispersed and less easily agglomerated at the time of manufacturing the composition. This is conceivably led by enhancement of a so-called penetrability into water acting as a dispersion medium, attributable to a bulk density relatively higher than a general bulk density, i.e., 50 g/L, that is to say, an increase in a weight per unit volume, resulting in easiness in dispersion.

Methods of controlling the bulk density of fumed silica include a method as follows.

A predetermined weight of fumed silica is measured and put in a rectangular parallelepiped filling container having one face thereof open, and the put fumed silica is pressurized in a direction perpendicular to the open face by a pressure member which is movable in the direction perpendicular to the open face along an inner wall of the container. At the time, the pressure is applied until a volume of pressurized fumed silica reaches a value obtained by calculation based on a desired bulk density and the put fumed silica. Fumed silica having a desired bulk density is thus obtained.

The fumed silica is obtained, for example, by hydrolyzing in the vapor phase silicon tetrachloride in an oxygenhydrogen flame, and it is also possible to use a commercialized product. Specific examples thereof include AEROSIL 90G and AEROSIL 130 (trade name, manufactured by Nippon Aerosil Co., Ltd.).

In view of the aqueous dispersibility or the like, a particle diameter of the fumed silica is, without restricting to particular one, preferably in a range of 5 nm to 80 nm on an average primary particle diameter obtained by measurement through alight scattering diffractometry. A specific surface area of the fumed silica is, also without restricting to particular one, preferably in a range of 50 m²/g to 150 m²/g obtained by measurement through the BET method, in view of the aqueous dispersibility or the like.

In view of maintaining the aqueous dispersibility at a high level over a long term and obtaining a high polishing rate, a content of the fumed silica of the invention is preferably in a range of 10% by weight to 30% by weight, more preferably in a range of 20% by weight to 28% by weight based on a total amount of the composition.

The semiconductor polishing composition according to an embodiment of the invention, within an extent that does not damage the aqueous dispersibility of the fumed silica, can contain general additives such as a polishing accelerator, an oxidizing agent, an organic acid, a complexing agent, a corrosion inhibitor and a surfactant.

As the polishing accelerator, one usually applied to the polishing composition can be used, and for instance, piperazine and amine compounds such as a primary amine compound having 1 to 6 carbon atoms can be cited. The piperazine includes piperazine having a substituent. Examples of the piperazine having a substituent includes piperazine obtained by substituting for a nitrogen atom a linear or branched-chain alkyl group which has 1 to 4 carbon atoms and may have a hydroxyl group, an amino group, etc. Specific examples thereof include N-aminoethyl piperazine, 1,4-bis(3-aminopropyl)piperazine, anhydrous piperazine, and piperazine hexahydrate. Examples of the primary amine compound having 1 to 6 carbon atoms include α-oxyethyl amine (α-aminoethyl alcohol), monoethanol amine (β-aminoethyl alcohol), aminoethylethanolamine, triethylenetetramine and ethylene diamine. Examples of the quaternary ammonium salt include tetramethylammonium chloride, tetramethylammonium hydroxide, dimethyldiethylammonium chloride, N,N-dimethyl morpholinium sulfate and tetrabutylammonium bromide. Among these, anhydrous piperazine is preferable. The polishing accelerators can be used singularly or in a combination of two or more thereof.

A content of the polishing accelerator can be, without restricting to particular one, appropriately selected from a wide range depending on various conditions such as a concentration and a particle diameter of fumed silica, and a kind of a component used in combination therewith, but is preferably in a range of about 0.001% by weight to 5% by weight based on a total amount of the composition.

Also as the oxidant, one usually applied to the polishing composition can be used, and for instance, potassium iodate, periodic acid, potassium iodide and iodic acid can be cited.

The oxidants can be used singularly or in a combination of two or more thereof.

A content of the oxidant can be, without restricting to particular one, appropriately selected from a wide range depending on various conditions such as a concentration and a particle diameter of fumed silica, and a kind of a component used in combination therewith, but is preferably in a range of about 0.001% by weight to 10% by weight based on a total amount of the composition.

Also as the organic acid, one usually applied to the polishing composition can be used, and there can be cited, for instance, monocarboxylic acids having 2 to 6 carbon atoms such as formic acid, acetic acid, propionic acid, butyric acid, valeric acid and lactic acid; dicarboxylic acids having 2 to 6 carbon atoms such as oxalic acid, malonic acid, succinic acid, tartaric acid, malic acid and fumaric acid; tricarboxylic acids having 3 to 6 carbon atoms such as citric acid and isocitric acid; aromatic carboxylic acids such as salicylic acid; and ascorbic acid. In the organic acids, salts of the carboxylic acids and ascorbic acid are contained as well. The organic acids can be used singularly or in a combination of at two or more thereof.

A content of the organic acid can be, without restricting to particular one, appropriately selected from a wide range depending on various conditions such as a concentration and a particle diameter of fumed silica, and a kind of a component used in combination therewith, but is preferably in a range of about 0.001% by weight to 5% by weight based on a total amount of the composition.

Also as the complexing agent, one usually applied to the polishing composition can be used, and there can be cited, for instance, ethylenediaminetetraacetic acid (EDTA), hydroxyethylethylenediaminetriacetic acid (HEDTA), diethylenetriaminepentaacetic acid (DTPA), nitrilotriacetic acid (NTA), triethylenetetraminehexaacetic acid (TTHA), hydroxyethyliminodiacetic acid (HIDA), dihydroxyethylglycine (DHEG), ethylene glycol-bis(β-aminoethylether)-N, N′-tetraacetic acid (EGTA) and 1,2-diaminocyclohexane-N,N, N′,N′-tetraacetic acid (CDTA). Among these, EDTA, DTPA, and TTHA are preferable, and TTHA is particularly preferable from an aspect of preventing the polished wafer from being contaminated by metal ions. The complexing agents can be used singularly or in a combination of two or more thereof.

A content of the complexing agent can be, without restricting to particular one, appropriately selected from a wide range depending on various conditions such as a concentration and a particle diameter of fumed silica, and a kind of a component used in combination therewith, but is preferably in a range of about 0.001% by weight to 5% by weight based on a total amount of the composition.

Also as the corrosion inhibitor, one usually applied to the polishing composition can be used, and there can be cited, for instance, benzotriazole, a derivative thereof (for instance, tolyltriazole having a methyl group substituted for a benzene ring of benzotriazole, benzotriazole-4-carboxylic acid having acarboxyl group substituted for abenzene ring of benzotriazole, alkyl (methyl, ethyl, propyl, butyl, and octyl) ester of benzotriazole-4-carboxylic acid, naphtotriazole, a derivative thereof, imidazole, quinaldic acid, and invar derivative. Among these, benzotriazole, a derivative thereof, imidazole, quinaldic acid, and invar derivative are preferable. The corrosion inhibitor can be used singularly or in a combination of two or more thereof.

A content of the corrosion inhibitor can be, without restricting to particular one, appropriately selected from a wide range depending on various conditions such as a concentration and a particle diameter of fumed silica, and a kind of a component used in combination therewith. However, from an aspect of not adversely affecting the compound but sufficiently exhibiting a performance of the compound, the content of the corrosion inhibitor is preferably in a range of about 0.001% by weight to 5% by weight based on a total amount of the composition.

Also as the surfactant, one usually applied to the polishing composition can be used, and there can be cited, for instance, anionic surfactants such as polyacrylic acid salt, alkylbenzene sulfonate, alkane sulfonate and α-olefin sulfonate; and nonionic surfactants such as fatty acid monoethanol amide, fatty acid diethanol amide, fatty acid ethylene glycol ester, monofatty acid glycerin ester, fatty acid sorbitan ester, fatty acid sucrose ester, alkylpolyoxyethylene ether, polyvinyl pyrrolidone, polyvinyl alcohol, hydroxyethyl cellulose, carboxymethyl cellulose and polyethylene glycol. Among these, polyacrylic acid salt, polyvinyl pyrrolidone and polyethylene glycol are preferable. The surfactants can be used singularly or in a combination of two or more thereof.

A content of the surfactant can be, without restricting to particular one, appropriately selected from a wide range depending on various conditions such as a concentration and a particle diameter of fumed silica, and a kind of a component used in combination therewith, but is preferably in a range of about 0.001% by weight to 3% by weight based on a total amount of the composition.

Furthermore, the semiconductor polishing composition according to an embodiment of the invention, within a range that does not damage preferable characteristics thereof, may contain alcohols. The alcohols act as dissolution aid, for instance, for the polishing accelerators such as piperazine and other components. When the alcohols are added, the dissolution stability of, for instance, the polishing accelerator can be improved. As the alcohols, it is possible to use known alcohols among which aliphatic saturated alcohols having 1 to 6 carbon atoms are preferable. Specific examples of the aliphatic saturated alcohols having 1 to 6 carbon atoms include linear or branched chain aliphatic saturated alcohol having 1 to 6 carbon atoms such as methanol, ethanol, propanol, isopropanol, butanol, isobutanol, tert-butanol, pentanol and hexanol.

The alcohols may have a substituent such as a hydroxyl group in an alkyl portion. Among these, methanol, ethanol and propanol having 1 to 3 carbon atoms are particularly preferable. The alcohols can be used singularly or in a combination of two or more thereof.

A content of the alcohol can be, without restricting to particular one, appropriately selected from a wide range depending on various conditions such as a kind of alcohol itself, kind and content of the other components, and a kind of a to-be-polished wafer. However, in view of enhancing the dissolution stability of the polishing accelerator without adversely affecting other properties such as dispersion stability of silica series abrasive grains, the content of the alcohol is preferably in a range of about 0.001% by weight to 10% by weight based on a total amount of the composition.

Water acting as a dispersion medium for the polishing compound of an embodiment of the invention is not particularly restricted; however, in view of the applications, ultrapure water, pure water, ion-exchanged water and distilled water are preferably used.

The semiconductor polishing composition according to the invention can be produced by use of a method that includes for instance (1) through (5) steps below.

(1) Preparation of Acidic Aqueous Solution

An acidic aqueous solution of which pH is 1 to 3, preferably around 2 and more preferably 2, is prepared. Now, the acid is not particularly restricted, and known acids can be used. Examples thereof include inorganic acids such as hydrochloric acid, nitric acid and sulfuric acid and organic acids such as phosphoric acid. Among these, hydrochloric acid is preferable. The acids can be used singularly or, as needs arise, in a combination of two or more thereof.

(2) Mixture of Acidic Aqueous Solution and Fumed Silica

Fumed silica is put in an acidic aqueous solution which is then mixed. At the time, fumed silica having a bulk density of 50 g/L or more and less than 100 g/L is used.

A concentration of the fumed silica is, without restricting to particular one, preferably in a range of 40 to 60% by weight to a total amount of the acidic aqueous solution and the fumed silica. A mixing time, which is also not particularly restricted, is preferably 1 hr or longer, more preferably 2 hr or longer. Further, during mixing, it is preferable to apply a high shearing force.

(3) Addition of Water to Mixture of Acidic Aqueous Solution and Fumed Silica

Water is added further to the mixture of the acidic aqueous solution and the fumed silica so that the concentration of fumed silica decreases by 5 to 15% by weight, preferably 10% by weight.

At that time, the concentration is not decreased to a desired level by one-time addition of water but preferably by a plurality of times of additions of water to gradually decrease the concentration of fumed silica. About two to four times of additions of water are preferable. A mixing time after the addition of water can be appropriately selected according to a lowering level of concentration of fumed silica.

Typically, the larger the lowering level is, the longer the mixing time may be set. For instance, to the mixture of the acidic aqueous solution and the fumed silica is added water of which amount is such that the concentration of fumed silica decreases by 1% by weight, and the obtained mixture is then mixed for about 5 to 60 min. Next, water is added at such an amount that the concentration of fumed silica decreases to the desired concentration, and the obtained mixture is then mixed for about 30 min to 2 hr.

(4) Preparation of Alkali Aqueous Solution

An alkali aqueous solution is prepared. As alkali contained in the alkali aqueous solution, known alkalis can be used and examples thereof include alkali metal hydroxides such as ammonium hydroxide, sodium hydroxide and potassium hydroxide; and alkaline earth metal hydroxides such as calcium hydroxide, barium hydroxide and magnesium hydroxide. Among these, alkali metal hydroxides are preferable and potassium hydroxide is more preferable. The alkalis may be used singularly or in a combination of two or more thereof as needs arise.

To the alkali aqueous solution, one or two or more general additives such as a polishing accelerator, an oxidant, an organic acid, a complexing agent, a corrosion inhibitor and a surfactant can be added.

The alkali aqueous solution is prepared so that the pH thereof is preferably 12 to 14.

(5) Preparation of Fumed Silica Dispersion Solution

To the alkali aqueous solution prepared in the step (4) is added the mixture of the acidic aqueous solution and the fumed silica prepared in the step (3), and then mixed. It is thus possible to obtain the semiconductor polishing compound acting as an aqueous dispersion solution for the fumed silica.

At the mixing, the mixture of the acidic aqueous solution and the fumed silica prepared in the step (3) is continuously or intermittently added little by little to the alkali aqueous solution prepared in the step (4). When the alkali aqueous solution prepared in the step (4) is added to the mixture of the acidic aqueous solution and the fumed silica prepared in the step (3), the agglomeration is easy caused, so that the aqueous dispersibility of the fumed silica is deteriorated; accordingly, a semiconductor polishing composition containing a desired property cannot be obtained.

Further, at the mixing, since the mixture prepared in the step (3) is strongly acidic while the alkali aqueous solution prepared in the step (4) is strongly alkaline, addition of the mixture prepared in the step (3) to the alkali aqueous solution prepared in the step (4) over a long time will easily cause agglomeration. Furthermore, it is thus preferable to conduct the addition for a length of time such that the agglomeration is not caused, depending on a concentration of the fumed silica in the mixture prepared in the step (3). Typically, the addition only needs to be carried out so as to be completed within 5 hr.

A mixing ratio of the mixture prepared in the step (3) and the alkali aqueous solution prepared in the step (4) is not particularly restricted. In view of setting the concentration of fumed silica in the to-be-obtained aqueous dispersion solution so as to fall in a range appropriate for polishing, the mixture only needs to be made so that the pH of the obtained fumed silica aqueous dispersion solution is preferably 10 to 12, more preferably around 11, and particularly preferably 11.

(6) Classification Process

The semiconductor polishing composition prepared in the step (5) is, as needs arise, subjected to a classification operation. Known classification method can be applied and for instance, filtration can be cited. As a filter, a depth filter having filtration accuracy of about 1 to 5 μm is used.

When a wafer is polished with the polishing composition of an embodiment of the invention, except that, in place of an existing polishing composition, the polishing composition of an embodiment of the invention is used, the polishing can be carried out similarly as ever.

The polishing composition of an embodiment of the invention can be used as a polishing composition generally in the CMP processing of a wafer. Specifically, the polishing composition can be preferably used to polish a wafer having a thin film formed thereon. The thin film formed on the wafer includes: a film of a metal such as W, Cu, Ti and Ta; a film of ceramics such as TiN, TaN and Si₃N₄; a film of oxide such as SiO₂ and p-TEOS; and a low dielectric film such as a HSQ film, a methylated HSQ film, a SiLK film and a porous film. Furthermore, the polishing composition of an embodiment of the invention, without restricting to the CMP polishing of the semiconductor wafer, can be preferably used when, in the applications other than the above-mentioned applications, metals and ceramics are polished.

Hereinbelow, examples and comparative examples of embodiments of the invention will be described.

### EXAMPLES

### Example 1

[Preparation of Mixture of Acidic Aqueous Solution and Fumed Silica]

To ultrapure water, a 0.01N hydrochloric acid aqueous solution was added and the pH was adjusted to 2. To the hydrochloric acid aqueous solution, fumed silica (bulk density : 50 g/L, average primary particle diameter: 20 nm and specific surface area: 90 m²/g) was added followed by stirring for 2 hr 30 min, and thereby a mixture of the acidic aqueous solution and the fumed silica of which fumed silica concentration is 50% by weight was prepared.

Next, to the above mixture, ultrapure water was added followed by mixing for 30 min to prepare a mixture of the acidic aqueous solution and the fumed silica, the mixture of which fumed silica concentration is 49% by weight.

Furthermore, to the above mixture, ultrapure water was added followed by mixing for 1 hr to prepare a mixture of the acidic aqueous solution and the fumed silica, the mixture of which fumed silica concentration is 40% by weight. The pH of the mixture was 2.

The mixings all were carried out under application of a shearing force with a high-shearing dispersion unit (trade name: T.K. HIVIS DISPER MIX, manufactured by Tokushu Kika Kogyo Co., Ltd.).

[Preparation of Alkali Aqueous Solution]

To ultrapure water, a 0.8% by weight potassium hydroxide aqueous solution was added to prepare an alkali aqueous solution of pH 13.

[Preparation of Semiconductor Polishing Composition of an embodiment of the Invention]

To 26.7 kg of the alkali aqueous solution which was obtained as above and then stirred, 43.3 kg of the mixture obtained as above of the acidic aqueous solution and the fumed silica was added for 10 min followed by further mixing for 10 min to prepare a fumed silica aqueous dispersion solution.

The obtained fumed silica aqueous dispersion solution was filtered with a filter having filtration accuracy of 1 μm (trade name: Profile II, manufactured by Nippon Pall Co., Ltd.) to remove coarse agglomerated particles, with the result that the semiconductor polishing composition of the invention was prepared. The polishing composition had a fumed silica concentration of 25% by weight and the pH of 11.

### Example 2

Except that, in the preparation of the mixture of the acidic aqueous solution and the fumed silica, fumed silica having a bulk density of 70 g/L was used, similarly to Example 1, a semiconductor polishing composition was prepared.

### Example 3

Except that, in the preparation of the mixture of the acidic aqueous solution and the fumed silica, fumed silica having a bulk density of 75 g/L was used, similarly to Example 1, a semiconductor polishing composition was prepared.

### Example 4

Except that, in the preparation of the mixture of the acidic aqueous solution and the fumed silica, fumed silica having a bulk density of 80 g/L was used, similarly to Example 1, a semiconductor polishing composition was prepared.

### Comparative Example 1

Except that, in the preparation of the mixture of the acidic aqueous solution and the fumed silica, fumed silica having a bulk density of 100 g/L was used, similarly to Example 1, a semiconductor polishing composition was prepared.

Evaluation Method
The number of coarse particles

From each of the semiconductor polishing compounds obtained in Examples 1 to 4 and Comparative Example 1, 0.5 ml of the compound was extracted, and the number of fumed silica particles having a particle diameter of 0.5 μm contained in each of the compounds was measured by use of a particle sizer (trade name: Accusizer 780 APS, manufactured by Particle Sizing Systems Inc.). The measurement was carried out twice.

TABLE 1

| | | Number of |
|---|---|---|
| | Bulk Density | Coarse Particles |
| | [g/L] | [Particles/0.5 ml] |
| Example 1 | 50 g/L | 98,296 |
| Example 2 | 70 g/L | 112,453 |
| Example 3 | 75 g/L | 66,595 |
| Example 4 | 80 g/L | 99,016 |
| Comparative | 100 g/L | 141,933 |
| Example 1 | | |

It can be seen that the number of contained coarse particles is small in Examples 1 to 4 where fumed silica acting as abrasive grains is therefore dispersed sufficiently. Particularly in Example 3, the number of contained coarse particles is very small, and it can be therefore seen that a dispersion state is most preferable. By contrast, in Comparative Example 1, a large number of coarse particles are contained, and it can be therefore seen that a dispersion state thereof is deteriorated.

As described above, even when various manufacturing conditions including pH, a shearing force and a mixing time are the same, different bulk densities lead different dispersion states of the polishing compound. When the bulk density is 50 g/L or more and less than 100 g/L, a preferable dispersion state can be obtained. On the other hand, when the bulk density is 100 g/L or more, it is difficult to practically use the compound.

The invention may be embodied in other specific forms without departing from the spirit or essential characteristics thereof. The present embodiments are therefore to be considered in all respects as illustrative and not restrictive, the scope of the invention being indicated by the appended claims rather than by the foregoing description and all changes which come within the meaning and the range of equivalency of the claims are therefore intended to be embraced therein.

### INDUSTRIAL APPLICABILITY

According to an embodiment of the invention, a mixture of an acidic aqueous solution and fumed silica, and an alkali aqueous solution are prepared, and the mixture is continuously or intermittently added to the alkali aqueous solution, and a bulk density of powder of the fumed silica before dispersed is preferably 50 g/L or more and less than 100 g/L and more preferably 75 g/L or more and 85 g/L or less.

When the bulk density of the fumed silica is less than 50 g/L, it is difficult to handle the powder and moreover, a transportation cost is very high. In a case where the bulk density is 100 g/L or more, the fumed silica is packed at the time of filling the container, resulting in difficulty of dispersion at the time of manufacturing the composition and furthermore, agglomeration easily caused on transportation or the like occasion after the manufacture. By setting the bulk density of the fumed silica to 50 g/L or more and less than 100 g/L, it is possible to realize a semiconductor polishing composition that can efficiently polish a semiconductor device with high accuracy at a high polishing speed while preventing fumed silica from being agglomerated and without causing a polishing flaw in the semiconductor device. Furthermore, by setting the bulk density so as to be higher than a conventional level, it is made easier to handle the powder, and the transportation cost can also be reduced.

Further, pH of the alkali aqueous solution is in a range of 12 to 14, and pH of the mixture is in a range of 1 to 3.

Further, according to an embodiment of the invention, a content of the fumed silica in an entire composition is in a range of 10% by weight to 30% by weight. This makes it possible to enhance dispersibility of the fumed silica and to further prevent agglomeration from being generated.

Further, according to an embodiment of the invention, the compound is prepared by adding, to an alkali aqueous solution of pH 12 to 14, a mixture of pH 1 to 3 made of an acidic aqueous solution and fumed silica. This makes it possible to further prevent agglomeration from being generated.

Further, according to an embodiment of the invention, the alkali aqueous solution contain one or two ore more additives selected from a polishing accelerator, an oxidant, an organic acid, a complexing agent, a corrosion inhibitor and a surfactant. Alkali contained in the alkali aqueous solution is one or two or more hydroxides selected from ammonium hydroxide, alkali metal hydroxide, and alkaline earth metal hydroxide. This makes it possible to enhance a polishing accuracy and a polishing speed.

What is claimed is:

1. A semiconductor polishing composition comprising:
fumed silica as abrasive grains,
the semiconductor polishing composition being obtained by preparing a mixture of an acidic aqueous solution and fumed silica having a bulk density of 50 g/L or more and less than 100 g/L, and an alkali aqueous solution so that pH of the mixture is in a range of 1 to 3 and pH of the alkali aqueous solution is in a range of 12 to 14, and adding the mixture to the alkali aqueous solution continuously or intermittently.

2. The semiconductor polishing composition of claim 1, wherein a content of the fumed silica is in a range of 10% by weight to 30% by weight based on a total amount of the composition.

3. (canceled)

4. (canceled)

5. (canceled)

6. The semiconductor polishing composition of claim 1, wherein the alkali aqueous solution contains one or two or more additives selected from a polishing accelerator, an oxidant, an organic acid, a complexing agent, a corrosion inhibitor and a surfactant.

7. The semiconductor polishing composition of claim 1, wherein alkali contained in the alkali aqueous solution is one or two or more hydroxides selected from ammonium hydroxide, alkali metal hydroxide, and alkaline earth metal hydroxide.

8. The semiconductor polishing composition of claim 2, wherein the alkali aqueous solution contains one or two or more additives selected from a polishing accelerator, an oxidant, an organic acid, a complexing agent, a corrosion inhibitor and a surfactant.

9. The semiconductor polishing composition of claim 2, wherein alkali contained in the alkali aqueous solution is one or two or more hydroxides selected from ammonium hydroxide, alkali metal hydroxide, and alkaline earth metal hydroxide.

10. The semiconductor polishing composition of claim 3, wherein alkali contained in the alkali aqueous solution is one or two or more hydroxides selected from ammonium hydroxide, alkali metal hydroxide, and alkaline earth metal hydroxide.

11. The semiconductor polishing composition of claim 8, wherein alkali contained in the alkali aqueous solution is one or two or more hydroxides selected from ammonium hydroxide, alkali metal hydroxide, and alkaline earth metal hydroxide.
